(19) United States
(12) Patent Application Publication
(10) Pub. No.: US 2011/0233506 A1
(43) Pub. Date: Sep. 29, 2011

(54) NONVOLATILE MEMORY DEVICE AND METHOD FOR MANUFACTURING SAME

(75) Inventors: Yoko IWAKAJI, Kanagawa-ken (JP); Jun HIROTA, Kanagawa-ken (JP); Moto YABUKI, Tokyo (JP)

(73) Assignee: Kabushiki Kaisha Toshiba, Tokyo (JP)

(21) Appl. No.: 12/873,604

(22) Filed: Sep. 1, 2010

(30) Foreign Application Priority Data
Mar. 23, 2010 (JP) 2010-066847
Jun. 16, 2010 (JP) 2010-137167

(51) Int. Cl. H01L 45/00; H01L 21/02

(52) U.S. Cl. 257/4; 438/382; 257/E45.001; 257/E21.004

(57) ABSTRACT

According to one embodiment, a nonvolatile memory device includes a first electrode, a second electrode, a resistance change portion and a select element. The resistance change portion is provided between the first electrode and the second electrode and configured to transition between a first resistance state and a second resistance state. The select element is provided between the resistance change portion and the first electrode and has a p-layer including a p-type semiconductor, an i-layer including an intrinsic semiconductor, and an n-layer including an n-type semiconductor. The select element contains an impurity having a smaller bandgap energy than the intrinsic semiconductor, and a concentration peak of the impurity in the i-layer is placed in a center portion of layer thickness of the i-layer.

### CROSS-REFERENCE TO RELATED APPLICATIONS

This application is based upon and claims the benefit of priority from the prior Japanese Patent Application No. 2010-066847, filed on Mar. 23, 2010 and the prior Japanese Patent Application No. 2010-137167, filed on Jun. 16, 2010; the entire contents of which are incorporated herein by reference.

### FIELD

Embodiments described herein relate generally to a nonvolatile memory device and a method for manufacturing the same.

### BACKGROUND

It has recently been discovered that a specific metal oxide material under application of a voltage exhibits two states, i.e., low resistance state and high resistance state, depending on the resistivity before the voltage application and the magnitude of the applied voltage. A novel nonvolatile memory device based on this phenomenon is drawing attention. This nonvolatile memory device is called ReRAM (resistance random access memory). As an actual device structure for the ReRAM, from the viewpoint of increasing the integration density, a three-dimensional cross-point structure is proposed (see, e.g., Patent Document 1). In this structure, a memory cell including a resistance change portion is located at each cross-point between the word line (WL) and the bit line (BL).

In the three-dimensional cross-point structure, when a voltage is applied to write data to a memory cell, a reverse voltage is applied also to other non-selected memory cells. Thus, each memory cell is provided with a select element in conjunction with the resistance change portion. The select element is a PIN silicon diode, for instance. In the PIN silicon diode, a silicon layer doped with p-type impurity (p-layer), a non-doped or low doped silicon layer (i-layer), and a silicon layer doped with n-type impurity (n-layer) are stacked.

Such a nonvolatile memory device can be operated in bipolar mode. In the bipolar mode of operation, the polarity of current and voltage in the set operation is opposite to that in the reset operation. However, in the bipolar mode of operation, with regard to the reverse bias characteristics of the select element, it is necessary to cause breakdown in the select element at a relatively low voltage.

### BRIEF DESCRIPTION OF THE DRAWINGS

FIG. 1 is a schematic cross-sectional view illustrating pillars and the surroundings of a nonvolatile memory device according to a first embodiment;

FIG. 2 is a schematic perspective view illustrating the nonvolatile memory device according to the first embodiment;

FIG. 3 is a graph showing an example of the impurity concentration profile of the select element;

FIG. 4 is a graph illustrating the voltage-current (V-I) characteristics of the select element;

FIG. 5 shows an example equivalent circuit of the nonvolatile memory device according to this embodiment;

FIG. 6 is a graph illustrating the transition of the resistance state of the resistance change portion;

FIG. 7 illustrates the state of voltage application to each memory cell in the set operation;

FIG. 8 illustrates the state of voltage application to each memory cell in the reset operation;

FIGS. 9 to 13 are process cross-sectional views illustrating a method for manufacturing a nonvolatile memory device according to a second embodiment; and

FIGS. 14A and 14B are schematic cross-sectional views describing alternative example configurations of the select element.

### DETAILED DESCRIPTION

In general, according to one embodiment, a nonvolatile memory device includes a first electrode, a second electrode, a resistance change portion and a select element. The resistance change portion is provided between the first electrode and the second electrode and configured to transition between a first resistance state and a second resistance state. The select element is provided between the resistance change portion and the first electrode, and has a p-layer including a p-type semiconductor, an i-layer including an intrinsic semiconductor, and an n-layer including an n-type semiconductor. The select element contains an impurity having a smaller bandgap energy than the intrinsic semiconductor, and a concentration peak of the impurity in the i-layer is placed in a center portion of layer thickness of the i-layer.

According to another embodiment, a method for manufacturing a nonvolatile memory device is disclosed. The method can include providing a first electrode in a substrate. The method can include providing a select element by forming an n-layer including an n-type semiconductor on the first electrode, forming an i-layer including an intrinsic semiconductor on the n-layer, adding an impurity having a smaller bandgap energy than the intrinsic semiconductor and having a concentration peak in the i-layer placed in a center portion of layer thickness of the i-layer, and forming a p-layer including a p-type semiconductor on the i-layer. The method can include providing a resistance change portion on the select element. In addition, the method can include providing a second electrode on the resistance change portion.

Embodiments of the invention will now be described with reference to the drawings.

The drawings are schematic or conceptual. The relationship between the thickness and the width of each portion, and the size ratio between the portions, for instance, are not necessarily identical to those in reality. Furthermore, the same portion may be shown with different dimensions or ratios depending on the figures.

In the specification and the drawings, the same components as those described previously with reference to earlier figures are labeled with like reference numerals, and the detailed description thereof is omitted as appropriate.

### First Embodiment

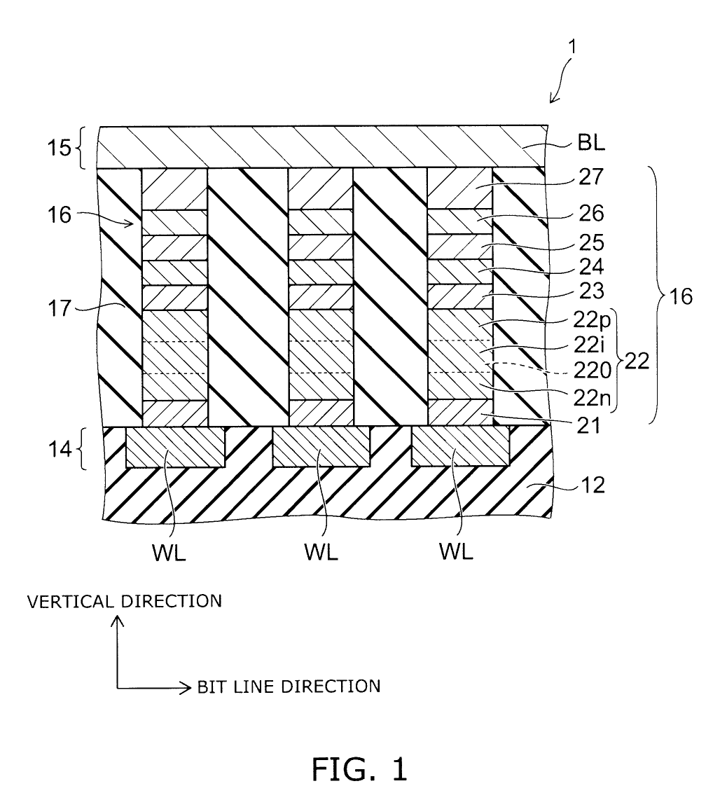

FIG. 1 is a schematic sectional view illustrating pillars and the surroundings of a nonvolatile memory device according to a first embodiment.

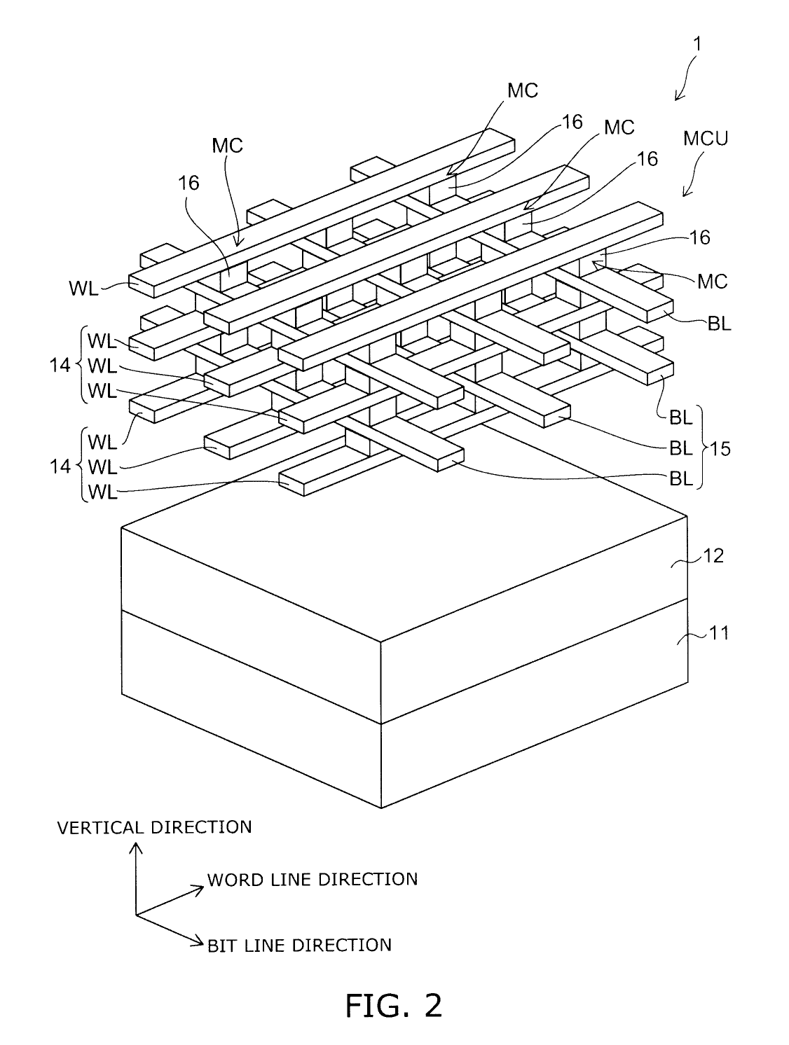

FIG. 2 is a schematic perspective view illustrating the nonvolatile memory device according to the first embodiment.

As shown in FIG. 1, the nonvolatile memory device 1 according to this embodiment includes a word line (first electrode) WL, a bit line (second electrode) BL, a resistance change portion 25 provided between the word line WL and the bit line BL, and a select element 22 provided between the resistance change portion 25 and the word line WL.

As shown in FIG. 2, in the nonvolatile memory device 1, the word line WL and the bit line BL cross each other. The resistance change portion 25 and the select element 22 are provided at the crossing position of the word line WL and the bit line BL. The resistance change portion 25 transitions between a first resistance state and a second resistance state in response to at least one of the applied electric field and the passed current.

In the nonvolatile memory device 1 according to this embodiment, it is assumed as an example that the first resistance state is the state of relatively low electrical resistance (low resistance state), and the second resistance state is the state of relatively high electrical resistance (high resistance state).

The select element 22 includes a p-layer 22p including a p-type semiconductor, an i-layer 22i including an intrinsic semiconductor, and an n-layer 22n including an n-type semiconductor. Here, the i-layer 22i contains an impurity 220 having a smaller bandgap energy than the intrinsic semiconductor. The concentration peak of this impurity 220 in the i-layer 22i is placed in the center portion of the layer thickness of the i-layer 22i. Here, the center portion of the layer thickness of the i-layer 22i refers to the range on the inner side of the impurity concentration peak of the n-layer 22n and the impurity concentration peak of the p-layer 22p.

In the nonvolatile memory device 1 according to this embodiment, such a select element 22 allows the set operation and the reset operation in the bipolar mode to be reliably performed. More specifically, because the i-layer 22i of the select element 22 contains the impurity 220 with the concentration peak as described above, the bandgap in the i-layer 22i is narrowed from the end portion of the n-layer 22n side and the p-layer 22p side toward the center portion.

Thus, the absolute value of the breakdown voltage of the select element 22 under reverse bias is lower than that in the case where the impurity 220 is not contained.

In the bipolar mode of operation of the nonvolatile memory device 1, when the select element 22 is reverse biased, the resistance state of the resistance change portion 25 undergoes transition at the breakdown voltage of the select element 22. By adding the impurity 220 to the i-layer 22i of the select element 22 to place its concentration peak in the center portion of the layer thickness of the i-layer 22i, the breakdown voltage of the select element 22 can be suitably configured. Hence, by configuring the breakdown voltage of the select element 22 with reference to the voltage of state transition of the resistance change portion 25, the set operation and the reset operation in the nonvolatile memory device 1 can be reliably performed.

Next, the nonvolatile memory device 1 according to this embodiment is described in detail.

As shown in FIG. 2, the nonvolatile memory device 1 includes a silicon substrate 11. A driver circuit (not shown) for the nonvolatile memory device 1 is formed in an upper portion and on the upper surface of the silicon substrate 11. An interlayer insulating film 12 illustratively made of silicon oxide is provided on the silicon substrate 11 so as to bury the driver circuit. A memory cell unit MCU is provided on the interlayer insulating film 12.

In the memory cell unit MCU, word line interconnection layers 14 and bit line interconnection layers 15 are alternately stacked via insulating layers. The word line interconnection layer 14 includes a plurality of word lines WL extending in one direction (hereinafter referred to as “word line direction”) parallel to the upper surface of the silicon substrate 11. The bit line interconnection layer 15 includes a plurality of bit lines BL extending in a direction (hereinafter referred to as “bit line direction”) being parallel to the upper surface of the silicon substrate 11 and crossing, such as being orthogonal to, the word line direction. The word line WL and the bit line BL are illustratively formed from tungsten (W). The adjacent word lines WL, the adjacent bit lines BL, and the word line WL and the bit line BL are not in contact with each other.

At the nearest point between each word line WL and each bit line BL, a pillar 16 extending in the direction (hereinafter referred to as “vertical direction”) perpendicular to the upper surface of the silicon substrate 11 is provided. The pillar 16 is formed between the word line WL and the bit line BL. One pillar 16 constitutes one memory cell MC. That is, the nonvolatile memory device 1 is a cross-point device in which a memory cell MC is located at each nearest point between the word line WL and the bit line BL. An interlayer insulating film 17 (see FIG. 1) illustratively made of silicon oxide is buried among the word line WL, the bit line BL, and the pillar 16.

In the following, an example configuration of the pillar 16 is described with reference to FIG. 1.

The pillar 16 is one of two types of pillars. In one type of pillar 16, the word line WL is located therebelow, and the bit line BL is located thereabove. In the other type of pillar 16, the bit line BL is located therebelow, and the word line WL is located thereabove. FIG. 1 shows a pillar 16 with the word line WL located therebelow and the bit line BL located thereabove. In this pillar 16, from bottom (word line WL side) to top (bit line BL side), a lower electrode film 21, a select element 22, an intermediate electrode film 23, a barrier metal 24, a resistance change portion 25, an upper electrode film 26, and a stopper film 27 are stacked in this order.

The lower electrode film 21 is in contact with the word line WL. The stopper film 27 is in contact with the bit line BL. The lower electrode film 21 is illustratively made of titanium nitride (TiN), and has a film thickness of e.g. 5-10 nm.

The resistance change portion 25 is illustratively formed from a metal oxide and can take two or more resistance levels. In the nonvolatile memory device 1 according to this embodiment, for instance, the resistance levels correspond to the first resistance state and the second resistance state. In the resistance change portion 25, the resistance state is switched by input of a prescribed electrical signal.

The select element 22 is illustratively made of polysilicon. The select element 22 includes, sequentially from the bottom side, an n-layer 22n having n⁺-type conductivity, an i-layer 22i including an intrinsic semiconductor, and a p-layer 22p having p⁺-type conductivity.

Here, in the pillar 16 with the bit line BL located therebelow and the word line WL located thereabove, the stacking order of the n-layer 22n, the i-layer 22i, and the p-layer 22p in the select element 22 is reversed. However, the rest of the stacking structure is similar to that of the aforementioned pillar 16 with the word line WL located therebelow.

The intermediate electrode film 23 illustratively contains titanium, silicon, and nitrogen. For instance, the intermediate electrode film 23 is formed from a compound made of titanium, silicon, and nitrogen. The barrier metal 24 formed on the intermediate electrode film 23 is illustratively made of titanium. The barrier metal 24 serves to reduce the interfacial resistance, for instance.

An upper electrode film 26 is provided on the resistance change portion 25. The upper electrode film 26 is illustratively made of titanium nitride (TiN). A stopper film 27 is provided on the upper electrode film 26. The stopper film 27 is illustratively made of tungsten (W).

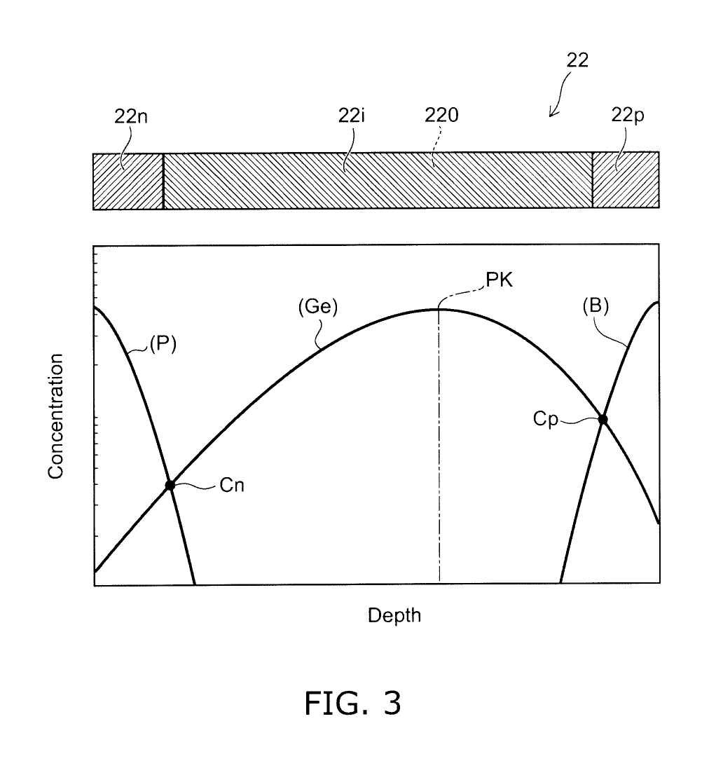

FIG. 3 is a graph showing an example of the impurity concentration profile of the select element.

In FIG. 3, the horizontal axis represents depth (vertical position) in the select element 22, and the vertical axis represents impurity concentration.

From left to right along the horizontal axis, FIG. 3 corresponds to the n-layer 22n, the i-layer 22i, and the p-layer 22p of the select element 22 in this order. Here, the impurity concentration in the n-layer 22n illustrated in FIG. 3 is the concentration of phosphorus (P) introduced into silicon. The impurity concentration in the i-layer 22i illustrated in FIG. 3 is the concentration of germanium (Ge) introduced into silicon. The impurity concentration in the p-layer 22p illustrated in FIG. 3 is the concentration of boron (B) introduced into silicon.

In the i-layer 22i of the select element 22, germanium (Ge) is introduced as an impurity 220. Germanium (Ge) has a smaller bandgap energy than silicon. In the i-layer 22i, the concentration peak PK of germanium (Ge), or the impurity 220, is placed in the center portion of the layer thickness of the i-layer 22i. That is, along the layer thickness of the i-layer 22i, the impurity concentration is high in the center portion, and low in the end portions (on the n-layer 22n side and the p-layer 22p side).

Because of such an impurity concentration profile in the i-layer 22i, the bandgap in the i-layer 22i is narrower as the concentration of the impurity 220 is higher. That is, in the i-layer 22i, the bandgap is narrowed from the end portion toward the center portion along the layer thickness. Thus, the breakdown voltage of the select element 22 under reverse bias is lower than that in the case where the impurity 220 is not contained in the i-layer 22i.

The breakdown voltage of the select element 22 is configured by the concentration and the concentration profile of the impurity 220 introduced into the i-layer 22i. Hence, without changing the layer thickness of the i-layer 22i, the breakdown voltage of the select element 22 can be adjusted by the introduced impurity 220.

Here, an example of the concentration profile of the impurity 220 based on germanium (Ge) is as follows.

The concentration at the intersection Cp between the concentration profile of the impurity of the i-layer 22i (germanium (Ge)) and the concentration profile of the impurity of the p-layer 22p (boron (B)), and the concentration at the intersection Cn between the concentration profile of the impurity of the i-layer 22i (germanium (Ge)) and the concentration profile of the impurity of the n-layer 22n (phosphorus (P)), are 1×10¹⁹ cm⁻³ or less. The concentration of the impurity of the i-layer 22i (germanium (Ge)) at the peak PK is 1×10²¹ cm⁻³ or more.

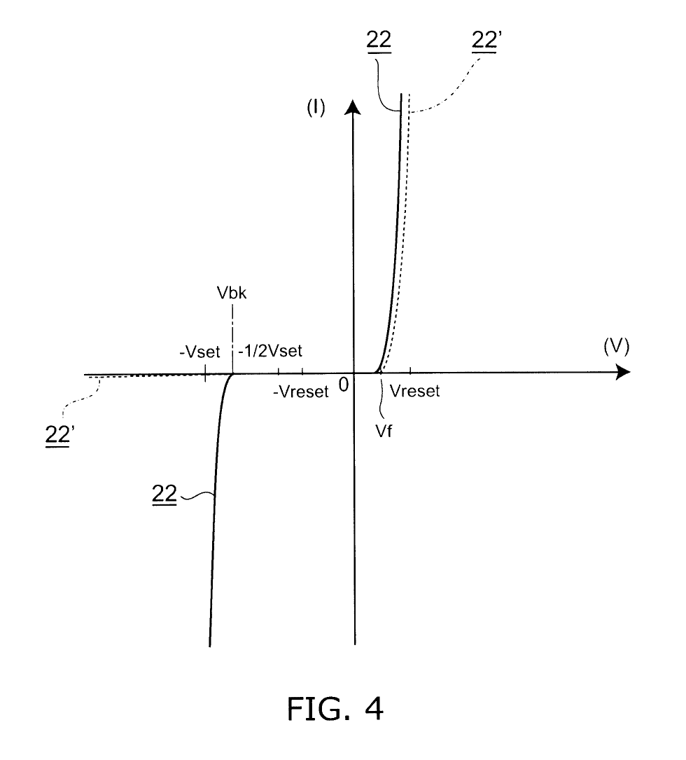

FIG. 4 is a graph illustrating the voltage-current (V-I) characteristics of the select element.

FIG. 4 illustrates the V-I characteristics of the select element 22 used in the nonvolatile memory device 1 according to this embodiment and the V-I characteristics of a select element 22′ according to a comparative example.

Here, in the select element 22′ according to the comparative example, no impurity is introduced into the i-layer.

In this graph, the horizontal axis represents voltage (V), and the vertical axis represents current (I). On the horizontal axis, the right side of the origin represents positive voltage (forward bias), and the left side of the origin represents negative voltage (reverse bias).

In the case where the select element 22 and the select element 22′ are forward biased, there is no substantial difference in the current characteristics. On the other hand, in the case of being reverse biased, although the select element 22′ does not undergo breakdown, the select element 22 undergoes breakdown upon application of a reverse bias exceeding a breakdown voltage Vbk. Thus, by introducing the impurity 220 into the i-layer 22i, breakdown can be caused at a prescribed voltage with reverse bias while maintaining the forward bias characteristics.

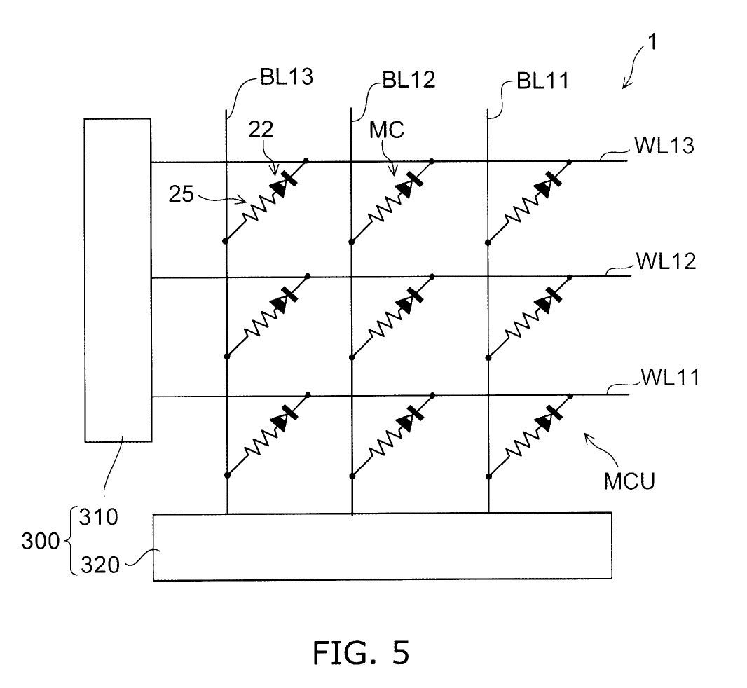

FIG. 5 shows an example equivalent circuit of the nonvolatile memory device according to this embodiment.

As an example for description, this figure shows an equivalent circuit for a total of nine memory cells MC, three horizontal by three vertical.

As shown in FIG. 5, the nonvolatile memory device 1 includes a memory cell unit MCU and a controller 300. The memory cell unit MCU includes a plurality of memory cells MC arranged in a matrix.

The controller 300 applies voltage to word lines WL (WL11-WL13) and bit lines BL (BL11-BL13). The controller 300 illustratively includes a word line circuit 310 connected to the word lines WL11, WL12, and WL13, and a bit line circuit 320 connected to the bit lines BL11, BL12, and BL13. The word line circuit 310 illustratively includes row decoders, and the bit line circuit 320 illustratively includes sense amplifier circuits. The word lines WL are selected by the word line circuit 310. The bit line circuit 320 detects data at read time, and holds write data at data write time, while controlling the voltage of the bit lines BL accordingly.

Various electrical signals are applied by the controller 300 to the resistance change portion 25 and the select element 22 provided at each of the cross-points where the word lines WL11, WL12, and WL13 three-dimensionally cross the bit lines BL11, BL12, and BL13.

By the electrical signal outputted from the controller 300 to the word lines WL11, WL12, and WL13, the resistance state of the resistance change portion 25 is controlled to one of the first resistance state and the second resistance state. These different resistance states are used as data for storing information.

Here, the operation of changing the resistance of the resistance change portion 25 from the second resistance state (high resistance state) to the first resistance state (low resistance state) is referred to as set operation. On the other hand, the operation of changing the resistance of the resistance change portion 25 from the first resistance state (low resistance state) to the second resistance state (high resistance state) is referred to as reset operation.

In the following, for simplicity of description, it is assumed that the resistance change portion 25 takes two resistance states, i.e., the high resistance state and the low resistance state. However, the resistance change portion 25 may take three or more, or four or more resistance states. That is, the nonvolatile memory device 1 may be a multivalued memory.

### Set Operation and Reset Operation

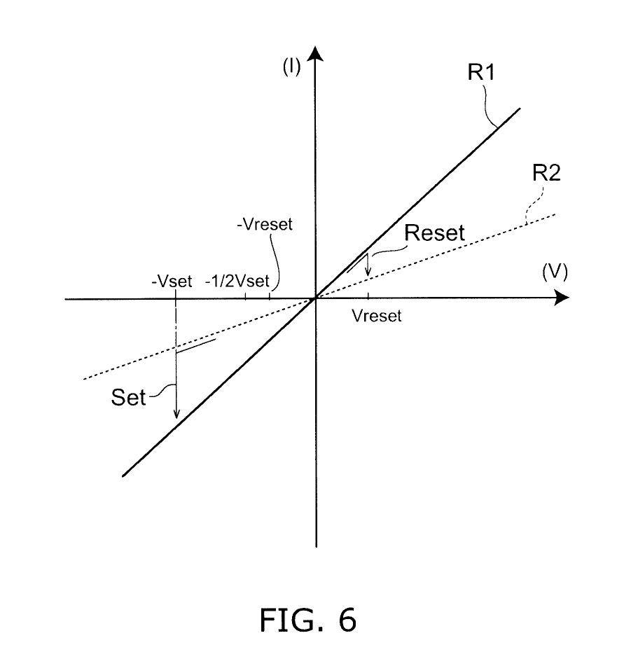

FIG. 6 is a graph illustrating the transition of the resistance state of the resistance change portion.

In this figure, the horizontal axis represents the voltage (V) applied to the resistance change portion 25, and the vertical axis represents the current (I) flowing in the resistance change portion 25.

In this figure, the V-I characteristic in the first resistance state (low resistance state) R1 is shown by a solid line, and the V-I characteristic in the second resistance state (high resistance state) R2 is shown by a dashed line.

The resistance state of the resistance change portion 25 transitions between the first resistance state R1 and the second resistance state R2.

The nonvolatile memory device 1 according to this embodiment is operated in bipolar mode. In the bipolar mode of operation, the polarity of current and voltage in the set operation is opposite to that in the reset operation.

For instance, in the reset operation, the resistance change portion 25 is applied with +Vreset on the positive polarity side. Thus, the resistance state of the resistance change portion 25 transitions from the first resistance state R1 to the second resistance state R2. On the other hand, in the set operation, the resistance change portion 25 is applied with −Vset on the negative polarity side. Thus, the resistance state of the resistance change portion 25 transitions from the second resistance state R2 to the first resistance state R1.

Here, the state of voltage application to each memory cell in the set operation and in the reset operation is described with reference to the equivalent circuit of a total of nine memory cells MC, three horizontal by three vertical.

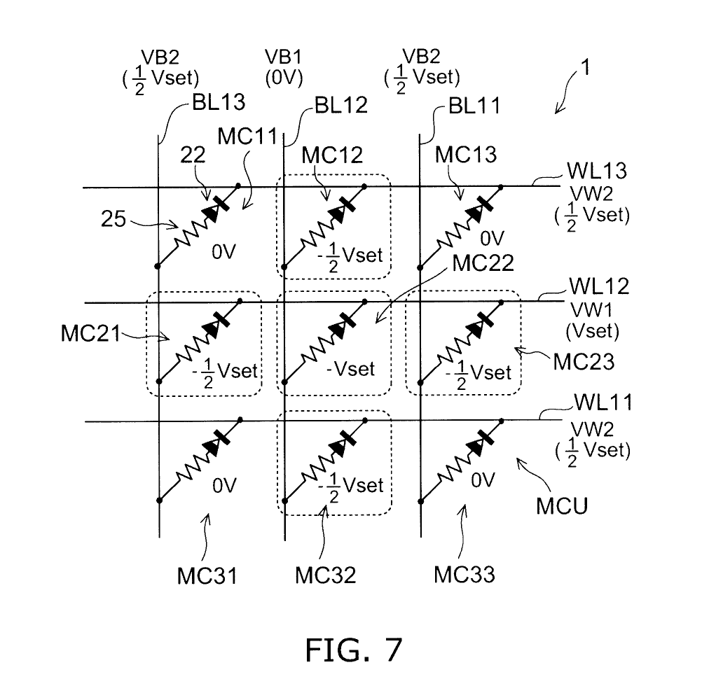

FIG. 7 illustrates the state of voltage application to each memory cell in the set operation.

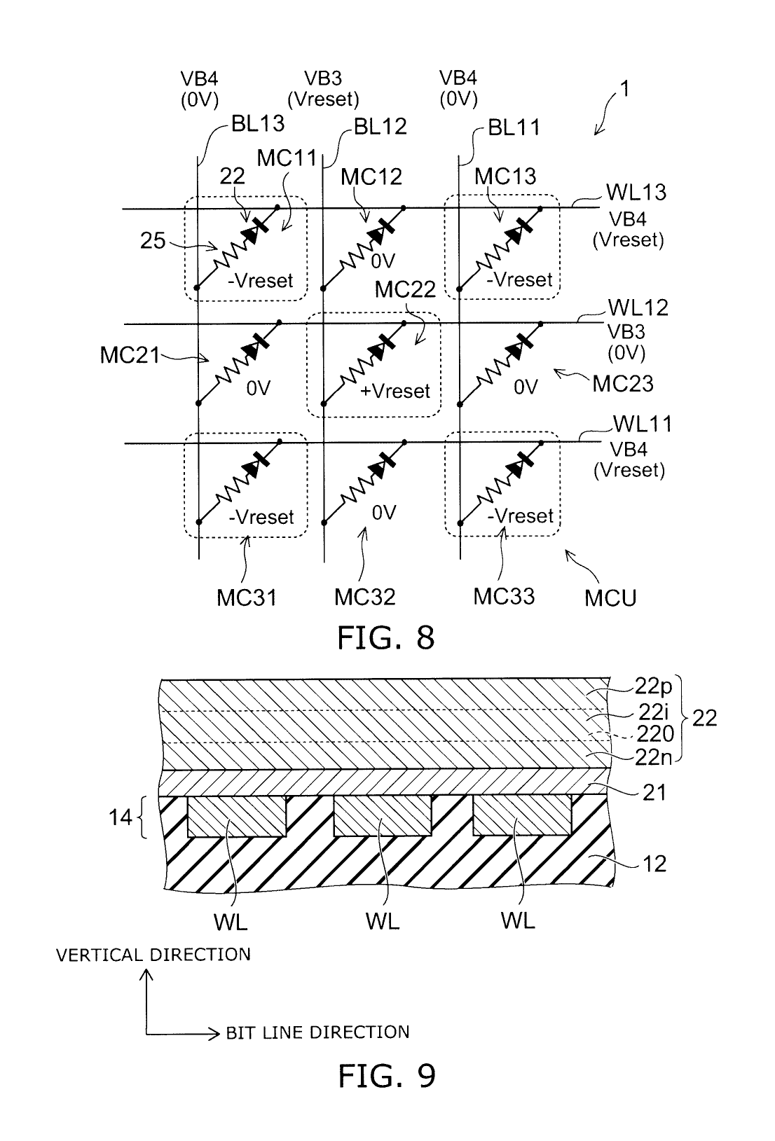

FIG. 8 illustrates the state of voltage application to each memory cell in the reset operation.

In FIGS. 7 and 8, the memory cell MC22 is the selected memory cell subjected to transition in the set operation and the reset operation. The memory cells except the memory cell MC22 are non-selected memory cells not subjected to transition in the set operation and the reset operation. Here, the operation is similar irrespective of which memory cell is the selected memory cell or the non-selected memory cell. In each of the set operation and the reset operation, the voltage applied to the memory cell MC is controlled by the controller 300.

As shown in FIG. 7, in the set operation, the potential VW1 of the word line WL12 electrically continuous with the selected memory cell MC22 is set to Vset, and the potential VB1 of the bit line BL12 electrically continuous with the selected memory cell MC22 is set to e.g. 0 V. On the other hand, the potential VW2 of the word lines WL11 and WL13 not electrically continuous with the selected memory cell MC22 is set to e.g. ½ Vset, and the potential VB2 of the bit lines BL11 and BL13 not electrically continuous with the selected memory cell MC22 is set to e.g. ½ Vset.

Here, the potentials VW2 and VB2 have the same value. Furthermore, the potentials VW2 and VB2 have the same polarity as Vset, and have a smaller absolute value than Vset. The potentials VW2 and VB2 are preferably half of Vset, i.e., ½ Vset. This is in order to make VB2−VW1 and VB1−VW2 equal.

In this set operation, the select element 22 of the selected memory cell MC22 is applied with VB1−VW1, i.e., a reverse bias of −Vset. Thus, the select element 22 undergoes breakdown. The resistance change portion 25 of the selected memory cell MC22 is applied with −Vset via the select element 22 in the breakdown state. Thus, the resistance state of the resistance change portion 25 transitions from the second resistance state to the first resistance state. That is, the set operation is performed on the selected memory cell MC22.

On the other hand, among the non-selected memory cells, in the memory cells MC11, MC13, MC31, and MC33, the select element 22 is applied with VB2−VW2, i.e., a potential of 0 V. Hence, the resistance change portion 25 is applied with no voltage, and the set operation is not performed thereon.

Furthermore, among the non-selected memory cells, in the memory cells MC12 and MC32, the select element 22 is applied with VB1−VW2, i.e., a reverse bias of −½ Vset. The select element 22 does not undergo breakdown at a reverse bias of −½ Vset. Hence, the resistance change portion 25 is applied with no voltage, and the set operation is not performed thereon.

Furthermore, among the non-selected memory cells, in the memory cells MC21 and MC23, the select element 22 is applied with VB2−VW1, i.e., a reverse bias of −½ Vset. The select element 22 does not undergo breakdown at a reverse bias of −½ Vset. Hence, the resistance change portion 25 is applied with no voltage, and the set operation is not performed thereon.

Next, as shown in FIG. 8, in the reset operation, the potential VW3 of the word line WL12 electrically continuous with the selected memory cell MC22 is set to e.g. 0 V, and the potential VB3 of the bit line BL12 electrically continuous with the selected memory cell MC22 is set to Vreset. On the other hand, the potential VW4 of the word lines WL11 and WL13 not electrically continuous with the selected memory cell MC22 is set to Vreset, and the potential VB4 of the bit lines BL11 and BL13 not electrically continuous with the selected memory cell MC22 is set to e.g. 0 V.

Here, the potentials VW3 and VB4 have the same value. Furthermore, Vreset is smaller than the absolute value of the difference VB2−VW1 between the potential VB2 and the potential VW1 used in the set operation illustrated in FIG. 7, or the absolute value of the difference VB1−VW2 between the potential VB1 and the potential VW2 used in the set operation illustrated in FIG. 7. This is in order not to reach the breakdown voltage of the select element 22 even if the select element 22 is applied with a reverse bias of −Vreset.

In this reset operation, the select element 22 of the selected memory cell MC22 is applied with VB3−VW3, i.e., a forward bias of +Vreset. Thus, a forward current flows in the select element 22. The resistance change portion 25 of the selected memory cell MC22 is applied with +Vreset via the select element 22. Thus, the resistance state of the resistance change portion 25 transitions from the first resistance state to the second resistance state. That is, the reset operation is performed on the selected memory cell MC22.

On the other hand, among the non-selected memory cells, in the memory cells MC12, MC21, MC23, and MC32, the select element 22 is applied with VB3−VW4 or VB4−VW3, i.e., a potential of 0 V. Hence, the resistance change portion 25 is applied with no voltage, and the reset operation is not performed thereon.

Furthermore, among the non-selected memory cells, in the memory cells MC11, MC13, MC31, and MC33, the select element 22 is applied with VB4−VW4, i.e., a reverse bias of −Vreset. The select element 22 does not undergo breakdown at a reverse bias of −Vreset. Hence, the resistance change portion 25 is applied with no voltage, and the reset operation is not performed thereon.

For such bipolar mode of operation, the select element 22 needs to have the characteristics capable of supplying the resistance change portion 25 with a current required for the transition operation under the voltages of both polarities (−Vset and +Vreset) for the set operation and the reset operation.

Specifically, the select element 22 needs to have at least the following characteristics (1)-(3).

(1) Sufficient conduction characteristic upon application of a forward bias of +Vreset.

(2) Sufficient conduction characteristic by breakdown upon application of a reverse bias of −Vset.

(3) Sufficient insulation characteristic upon application of a reverse bias of −½ Vset.

The V-I characteristics of the select element 22 shown in FIG. 4 satisfy all the above characteristics (1)-(3).

More specifically, when the select element 22 is applied with a forward bias of +Vreset, the select element 22 is in the ON state, achieving sufficient conduction characteristic. That is, the ON voltage Vf of the select element 22 is lower than the potential +Vreset used in the reset operation.

When the select element 22 is applied with a reverse bias of −½ Vset, the select element 22 is in the OFF state, achieving sufficient insulation characteristic. That is, the breakdown voltage Vbk of the select element 22 is lower than the potential −½ Vset. Here, because the reverse bias −Vreset has a smaller absolute value than −½ Vset, the select element 22 is in the OFF state, achieving sufficient insulation characteristic.

When the select element 22 is applied with a reverse bias of −Vset, the select element 22 reaches the breakdown voltage Vbk. That is, the select element 22 is in the ON state, achieving sufficient conduction characteristic.

In the select element 22 used in the memory cell MC of the nonvolatile memory device 1, the breakdown voltage Vbk is adjusted by configuring the concentration and the concentration profile of the impurity 220 introduced into the i-layer 22i. More specifically, by configuring the concentration and the concentration profile of the impurity 220 introduced into the i-layer 22i, the breakdown voltage Vbk of the select element 22 is adjusted so as to be lower than VB2−VW2 (e.g., −½ Vset) and higher than VB1−VW1 (e.g., −Vset).

Thus, in the bipolar mode of operation of the nonvolatile memory device 1, the set operation and the reset operation can be reliably performed.

### Second Embodiment

Next, an example method for manufacturing a nonvolatile memory device 1 according to a second embodiment is described.

FIGS. 9 to 13 are process sectional views illustrating the method for manufacturing the nonvolatile memory device 1 according to this embodiment.

First, as shown in FIG. 2, a driver circuit for driving the memory cell unit MCU is formed in the upper surface of a silicon substrate 11. Next, an interlayer insulating film 12 is formed on the silicon substrate 11. Next, contacts (not shown) reaching the driver circuit are formed in the interlayer insulating film 12.

Next, as shown in FIG. 9, tungsten is buried in an upper portion of the interlayer insulating film 12 by a damascene process, for instance. Thus, a plurality of word lines WL are formed parallel to each other so as to extend in the word line direction. These word lines WL form a word line interconnection layer 14. Next, titanium nitride (TiN) is deposited on the word line interconnection layer 14 to a thickness of e.g. 5-10 nm to form a lower electrode film 21. The lower electrode film 21 is a barrier film for suppressing reaction between tungsten forming the word line WL and silicon forming the select element 22.

Next, amorphous silicon is deposited on the lower electrode film 21. At this time, while depositing amorphous silicon, impurities are introduced to continuously form an n-layer 22n, an i-layer 22i, and a p-layer 22p.

More specifically, an n-layer 22n is formed by introducing an impurity serving as a donor for silicon, such as phosphorus (P), while depositing amorphous silicon.

Subsequently, an i-layer 22i is formed by depositing amorphous silicon with germanium (Ge), for instance, added thereto as an impurity 220. Here, the added amount of germanium (Ge) is e.g. 5 wt % or more and 30 wt % or less.

Subsequently, a p-layer 22p is formed by introducing an impurity serving as an acceptor for silicon, such as boron (B), while depositing amorphous silicon.

Thus, a select element 22 made of a PIN silicon diode is formed. By way of example, the film thickness of the n-layer 22n is e.g. 2 nm or more and 15 nm or less. The phosphorus concentration is e.g. 1×10²⁰ cm⁻³ or more and 1×10²¹ cm⁻³ or less. The film thickness of the i-layer 22i is e.g. 50 nm or more and 120 nm or less. The film thickness of the p-layer 22p is e.g. 2 nm or more and 15 nm or less. The boron concentration is e.g. 1×10²⁰ cm⁻³ or more and 2×10²¹ cm⁻³ or less.

Here, ion implantation may also be used as a method for introducing impurities into the n-layer 22n, the i-layer 22i, and the p-layer 22p. More specifically, an n-layer 22n can be formed by film formation of polysilicon followed by ion implantation of phosphorus (P) or arsenic (As). An i-layer 22i can be formed by film formation of polysilicon followed by ion implantation of germanium (Ge). A p-layer 22p can be formed by film formation of polysilicon followed by ion implantation of boron (B).

In this formation of the select element 22, the concentration peak of the impurity 220 introduced into the i-layer 22i is adjusted so as to be placed in the center portion of the layer thickness of the i-layer 22i. Thus, the breakdown voltage Vbk of the select element 22 is adjusted.

In any method for impurity doping, after forming the p-layer 22p, non-doped silicon may be formed on the p-layer 22p. Here, the non-doped silicon layer includes a region having a lower concentration of impurity (boron (B)) than the p-layer 22p as well as a region not doped with impurity.

Furthermore, in any method for impurity doping, after forming the n-layer 22n, non-doped silicon may be formed on the n-layer 22n. Here, the non-doped silicon layer includes a region having a lower concentration of impurity (phosphorus (P) or arsenic (As)) than the n-layer 22n as well as a region not doped with impurity.

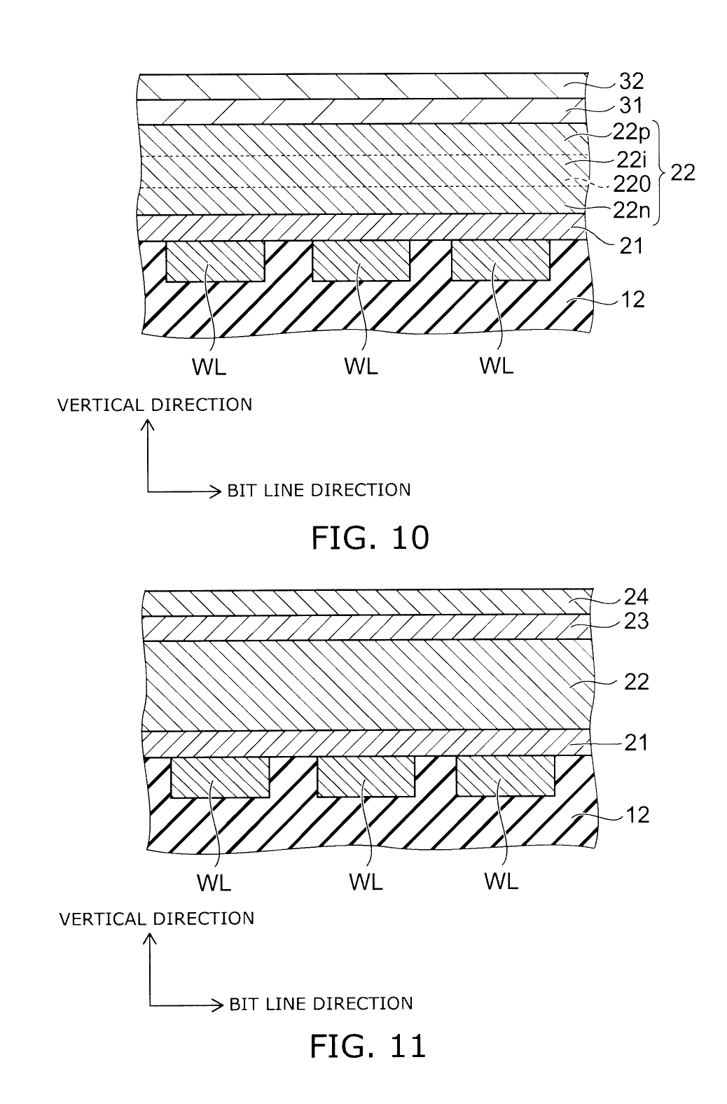

Next, as shown in FIG. 10, a titanium layer 31 made of titanium (Ti) is formed on the select element 22. At this time, the upper surface of the select element 22 is reduced, and natural oxide film is removed. The titanium layer 31 has a thickness of e.g. 0.5-2 nm. Next, a titanium nitride layer 32 made of titanium nitride (TiN) is formed on the titanium layer 31. The titanium nitride layer 32 has a thickness of e.g. 10 nm.

Next, as shown in FIG. 11, heat treatment is performed. For instance, the temperature of this heat treatment is 500° C. or more and 700° C. or less, and more particularly 600° C. The duration is illustratively 1 minute. Thus, into the titanium layer 31, silicon diffuses from the select element 22, and nitrogen diffuses from the titanium nitride layer 32, each reacting with titanium. Consequently, an intermediate electrode film 23 made of TiSiN is formed. Furthermore, part of the titanium nitride layer 32 remains also after the reaction as a barrier metal 24 made of titanium nitride (TiN).

Here, the intermediate electrode film 23 may be formed between the n-layer 22n and the lower electrode film 21, besides on the p-layer 22p.

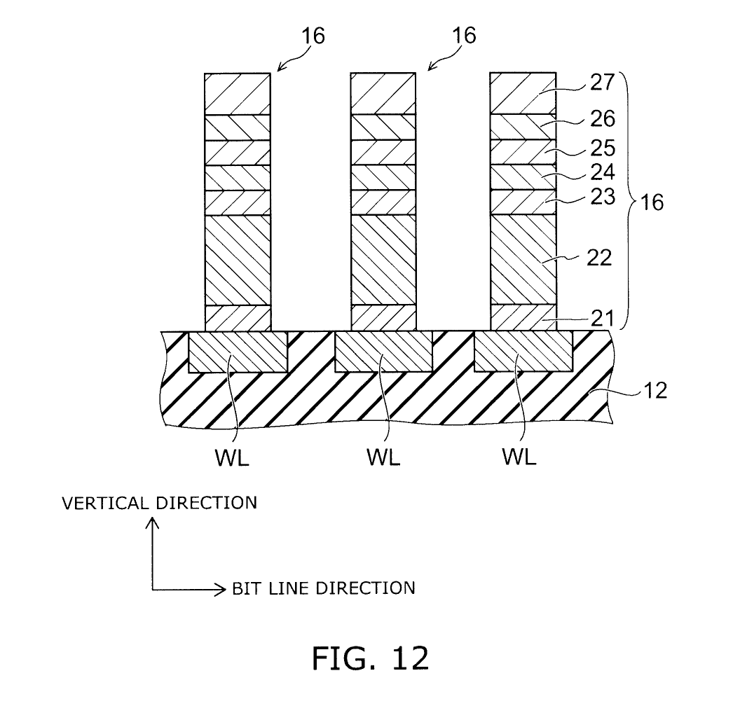

Next, as shown in FIG. 12, a resistance change portion 25 is formed on the barrier metal 24. Next, an upper electrode film 26 is formed on the resistance change portion 25. Then, a stopper film 27 illustratively made of tungsten is formed thereon. Next, a silicon oxide film using TEOS (tetraethyl orthosilicate) as a raw material, and a silicon nitride film are formed to form a mask material for patterning. This mask material is patterned by lithography to form a mask pattern (not shown).

Next, this mask pattern is used as a mask to perform RIE (reactive ion etching) so that the stopper film 27, upper electrode film 26, resistance change portion 25, barrier metal 24, intermediate electrode film 23, select element 22, and lower electrode film 21 are selectively removed and divided along both the word line direction and the bit line direction. Thus, a plurality of pillars 16 are formed on each word line WL. The aspect ratio of the pillar 16 is illustratively 4 or more.

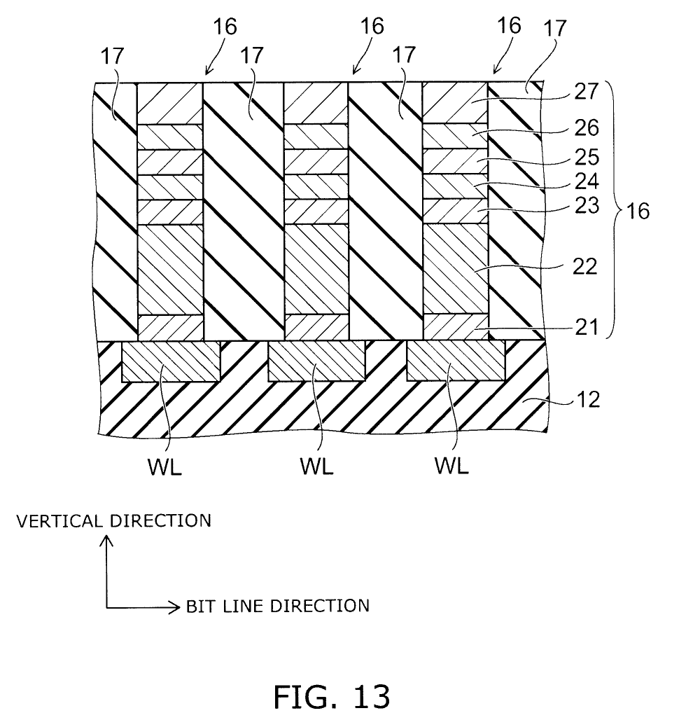

Next, as shown in FIG. 13, for instance, an insulating film, such as a silicon oxide film, is deposited by CVD (chemical vapor deposition) using TEOS as a raw material so as to bury the pillars 16.

Next, the stopper film 27 is used as a stopper to perform CMP (chemical mechanical polishing), thereby planarizing the upper surface of the silicon oxide film. Thus, an interlayer insulating film 17 made of silicon oxide is formed between the pillars 16. At this time, the upper surface of the stopper film 27 is exposed at the upper surface of the interlayer insulating film 17.

Next, as shown in FIG. 1, another interlayer insulating film (not shown) is formed on the interlayer insulating film 17, and bit lines BL are formed by a damascene process. More specifically, a trench is formed in a region of the interlayer insulating film where a bit line BL is to be formed. A interconnection material such as tungsten is deposited to fill in the trench. The portion of tungsten deposited outside the trench is removed by CMP. Thus, bit lines BL made of tungsten are formed. These bit lines BL form a bit line interconnection layer 15. Each bit line BL is connected to the upper surface of a plurality of pillars 16 arranged in the bit line direction. Thus, each pillar 16 is formed between the word line WL and the bit line BL, and connected to the word line WL and the bit line BL.

Next, pillars 16 are formed on the bit line BL. In forming this pillar 16, the stacking order of the n-layer 22n, the i-layer 22i, and the p-layer 22p in the select element 22 is reversed with respect to the aforementioned pillar 16 formed on the word line WL. Subsequently, by a similar method, a word line interconnection layer 14, a plurality of pillars 16, a bit line interconnection layer 15, and a plurality of pillars 16 are formed repetitively. Thus, the structure as shown in FIG. 2 is fabricated.

Next, heat treatment is performed at a temperature of e.g. 700° C. or more and 900° C. or less for a duration of e.g. 3 seconds or more and 80 seconds or less. Thus, silicon forming the select element 22 is crystallized into polysilicon, and the impurity contained in this silicon is activated. Thus, the memory cell unit MCU is formed. Consequently, the nonvolatile memory device 1 according to this embodiment is manufactured.

### Alternative Example Configurations of the Select Element

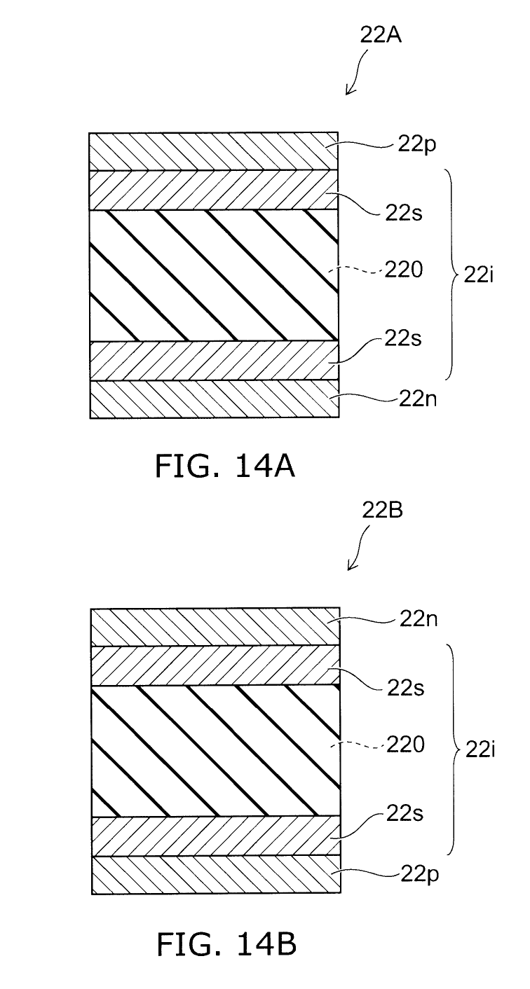

FIGS. 14A and 14B are schematic sectional views illustrating alternative example configurations of the select element.

FIG. 14A shows an example configuration of a select element 22A including an n-layer, an i-layer, and a p-layer stacked in this order from bottom. FIG. 14B shows an example configuration of a select element 22B including a p-layer, an i-layer, and an n-layer stacked in this order from bottom.

In the select elements 22A and 22B, a non-doped silicon layer 22s is provided on each of the n-layer 22n side of the i-layer 22i and the p-layer 22p side of the i-layer 22i. That is, the i-layer 22i includes a center region doped with an impurity 220, such as germanium (Ge), and end portions (silicon layers 22s) not doped with impurity.

By providing the silicon layers 22s in the i-layer 22i, the concentration peak of the impurity 220 in the i-layer 22i can be placed more accurately in the center portion of the layer thickness of the i-layer 22i. More specifically, by adjusting the layer thickness of the silicon layer 22s, the spread of the concentration profile of the impurity 220 in the i-layer 22i can be adjusted. Thus, the bandgap of the i-layer 22i in the select element 22 can be accurately adjusted, and the breakdown voltage can be precisely adjusted.

In the nonvolatile memory device 1 thus manufactured, in forming the select element 22, the i-layer 22i is added with the impurity 220 to place its concentration peak in the center portion of the layer thickness of the i-layer 22i. Thus, the breakdown voltage of the select element 22 can be appropriately configured. Hence, the breakdown voltage of the select element 22 can be configured with reference to the voltage of state transition of the resistance change portion 25. This serves to manufacture a nonvolatile memory device 1 in which the set operation and the reset operation can be reliably performed.

The embodiments of the invention and the variations thereof have been described. However, the invention is not limited to these examples. For instance, those skilled in the art can suitably modify the above embodiments and the variations thereof by addition, deletion, or design change of components, and can suitably combine the features of the embodiments with each other. Such modifications and combinations are also encompassed within the scope of the invention as long as they fall within the spirit of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A nonvolatile memory device comprising:
a first electrode;
a second electrode;
a resistance change portion provided between the first electrode and the second electrode and configured to transition between a first resistance state and a second resistance state; and
a select element provided between the resistance change portion and the first electrode, the select element having a p-layer including a p-type semiconductor, an i-layer including an intrinsic semiconductor, and an n-layer including an n-type semiconductor, the select element containing an impurity having a smaller bandgap energy than the intrinsic semiconductor, a concentration peak of the impurity in the i-layer being placed in a center portion of layer thickness of the i-layer.

2. The device according to claim 1, wherein
the first electrode extending in a first direction is provided in a plurality,
the second electrode extending in a second direction crossing the first direction is provided in a plurality, and
the resistance change portion and the select element are provided between each of the plurality of first electrodes and each of the plurality of second electrodes.

3. The device according to claim 1, further comprising:
a controller configured to apply voltage to the first electrode and the second electrode,
the controller being operative for:
applying a forward bias to the select element when causing the resistance change portion to transition from the first resistance state to the second resistance state; and
applying a reverse bias to the select element when causing the resistance change portion to transition from the second resistance state to the first resistance state.

4. The device according to claim 3, wherein the controller is operative for:
applying voltage for causing breakdown in the select element to the resistance change portion when causing the resistance change portion to transition from the second resistance state to the first resistance state.

5. The device according to claim 4, wherein the controller is operative for:
applying voltage different from the voltage for causing breakdown in the select element to the resistance change portion when causing the resistance change portion to maintain the resistance state.

6. The device according to claim 1, wherein
the intrinsic semiconductor is silicon, and
the impurity is germanium.

7. The device according to claim 1, wherein the resistance change portion in the first resistance state has a lower resistance than in the second resistance state.

8. The device according to claim 1, wherein breakdown voltage of the select element is configured with reference to voltage at which the resistance state of the resistance change portion transitions.

9. The device according to claim 1, wherein the first electrode and the second electrode cross each other.

10. The device according to claim 1, wherein the select element includes the n-layer, the i-layer, and the p-layer sequentially provided from the first electrode side.

11. The device according to claim 1, wherein the select element is formed from polysilicon.

12. The device according to claim 1, wherein the peak concentration in the i-layer is 1×10²¹ cm⁻³ or more.

13. The device according to claim 3, wherein the controller is operative for:
applying a potential Vset to the first electrode electrically continuous with the resistance change portion subjected to a transition from the second resistance state to the first resistance state, and applying a reference potential to the second electrode electrically continuous with the resistance change portion subjected to the transition; and
applying a potential ½ Vset to the first electrode and the second electrode electrically continuous with the resistance change portion not subjected to the transition.

14. The device according to claim 13, wherein the select element is turned to a non-conducting state when reverse biased with the potential ½ Vset.

15. The device according to claim 13, wherein the select element undergoes a breakdown when reverse biased with the potential Vset.

16. The device according to claim 3, wherein the controller is operative for:
applying a reference potential to the first electrode electrically continuous with the resistance change portion subjected to a transition from the first resistance state to the second resistance state, and applying a potential Vreset to the second electrode electrically continuous with the resistance change portion subjected to the transition; and
applying the potential Vreset to the first electrode electrically continuous with the resistance change portion not subjected to the transition, and applying the reference potential to the second electrode electrically continuous with the resistance change portion not subjected to the transition.

17. The device according to claim 16, wherein the select element is turned to a conducting state when forward biased with the potential Vreset.

18. The device according to claim 3, wherein the controller is configured to apply voltage to the select element subjected to a transition so that the voltage applied to the select element subjected to a transition from the first resistance state to the second resistance state is opposite in polarity to the voltage applied to the select element subjected to a transition from the second resistance state to the first resistance state.

19. The device according to claim 1, wherein in the select element, a non-doped semiconductor layer is provided on each of the n-layer side of the i-layer and the p-layer side of the i-layer.

20. A method for manufacturing a nonvolatile memory device, comprising:
providing a first electrode in a substrate;
providing a select element by forming an n-layer including an n-type semiconductor on the first electrode, forming an i-layer including an intrinsic semiconductor on the n-layer, adding an impurity having a smaller bandgap energy than the intrinsic semiconductor and having a concentration peak in the i-layer placed in a center portion of layer thickness of the i-layer, and forming a p-layer including a p-type semiconductor on the i-layer;
providing a resistance change portion on the select element; and
providing a second electrode on the resistance change portion.
